(19) United States
(12) Patent Application Publication
(10) Pub. No.: US 2023/0065957 A1
(43) Pub. Date: Mar. 2, 2023

(54) METHOD FOR DETERMINING THE SERVICE LIFE OF A SWITCHING DEVICE

(71) Applicant: Robert Bosch GmbH, Stuttgart (DE)

(72) Inventor: Michael Haas, Stuttgart (DE)

(21) Appl. No.: 17/893,324

(22) Filed: Aug. 23, 2022

(30) Foreign Application Priority Data
Aug. 24, 2021 (DE) 102021209246.2

(51) Int. Cl. G01R 31/327; G06N 3/08

(52) U.S. Cl. CPC G01R 31/327; G06N 3/08

(57) ABSTRACT

A method for determining the service life of a switching device, comprising the steps of:
a) providing a neural network having at least two input variables and an output variable;
b) determining at least a current variable, which represents a current flowing through the switching device, and a switching device state variable, which represents a sticking or jammed or fused switching device;
c) inputting at least the current variable and the switching device state variable as input variables into the neural network;
d) determining a remaining service life of the switching device by means of the neural network.

A method for training a neural network for determining the service life of a switching device, a corresponding device for determining the service life, a corresponding computer program, and a machine-readable storage medium with the computer program.

### BACKGROUND OF THE INVENTION

The present invention relates to a method for determining the service life of a switching device, a method for training a neural network for determining the service life of a switching device, a device for determining the service life of a switching device, a corresponding computer program, and a machine-readable storage medium with the computer program.

Switching devices are typically used in vehicles in order to electrically connect or disconnect energy storage units, e.g., batteries, to or from the on-board electrical system. The on-board electrical system can be a high-voltage on-board electrical system or a low-voltage on-board electrical system. Depending upon the vehicle or battery type, there are different topologies and structures of the switching devices. An electronic control unit monitors the operation of the switching devices and determines their state of health, i.e., their ability to switch according to their actuation. For this purpose, the manufacturer of a corresponding switching device generally makes corresponding specifications. The currents flowing through the switching device are divided into different classes by current amount, wherein each class has an upper limit for a corresponding number of current events. Furthermore, there is a class for events with a sticking, jammed, or fused switching device, which likewise has an upper limit for the corresponding events. The state of health of the switching device is determined as a function of the number of events of the classes still possible before reaching the respective upper limit.

Document US 2015/0088361 A1 discloses a method for monitoring the state of health of a switching device, wherein the state of health is determined as a function of a current variable.

Document WO 2020/087285 discloses a system for monitoring the state of health of a switching device of a battery, wherein the state of health is determined as a function of a current variable.

### SUMMARY OF THE INVENTION

A neural network with at least two input variables and an output variable is provided. Advantageously, the neural network has already been trained accordingly—for example, using the training method according to the invention described further below.

At least a current variable, which represents a current flowing through the switching device, and a switching device state variable, which represents a sticking or jammed or fused switching device, are determined. Typically, the corresponding time stamp is determined and stored for both variables.

The determined current variable and the determined switching device state variable are input into the neural network as input variables. The remaining service life of the switching device is determined by means of the neural network.

The method is advantageous, since a more precise determination of the state of health of the switching device is thereby made possible. Furthermore, the knowledge of the remaining service life can be used to estimate a time point at which the switching device should be changed, so that a disadvantageous failure of the switching device is prevented.

The method can be computer-implemented.

Expediently, the current variable is a continuous variable, and the switching device state variable is a discrete variable. This is advantageous, since the electrical current is continuously detected, and the switching device typically has the two states, “open” or “closed.”

Expediently, the neural network is trained by means of monitored learning. This is advantageous, since corresponding training data can be easily generated by means of laboratory tests and experiments.

Expediently, at least the method steps of providing the neural network and of input into the neural network are carried out in a cloud-based device. This can in particular be a server system which is not located at the same site as the switching device. This is advantageous, since more computing power and storage capacity are typically available there, and very complex neural networks can thus also be used.

Furthermore, the invention relates to a method for training a neural network for determining the service life of a switching device, having the steps described below.

Data sets are provided that comprise at least a current variable, which represents a current flowing through the switching device, and a switching device state variable, which represents a sticking or jammed or fused switching device, and an associated service life variable, which represents a service life of the switching device.

Furthermore, a neural network is provided having at least two input variables, e.g., for the current variable and the switching device state variable, and an output variable, e.g., for the service life variable.

At least the current variable and the switching device state variable are then input as input variables into the neural network.

The output variable of the neural network is compared with the corresponding service life variable provided. Thus, a comparison is made between the output of the neural network and the service life variable determined by, for example, testing.

This allows parameters of the neural network to be adapted as a function of the comparison.

The method is advantageous, since a well-adapted neural network is thereby created which can reliably determine the service life of a switching device.

The invention further relates to a device for determining the service life of a switching device, which comprises at least one means configured to carry out all the steps of a method according to the invention for determining the service life. The above-mentioned advantages can therewith be realized.

The invention further relates to a computer program that comprises commands which, when the program is executed by a computer, cause the computer to carry out the steps of the method according to the invention for determining service life and/or the steps of the method according to the invention for training a neural network for determining the service life. The above-mentioned advantages can therewith be realized.

The invention also relates to a machine-readable storage medium on which the computer program according to the invention is stored. The above-mentioned advantages can therewith be realized.

### BRIEF DESCRIPTION OF THE DRAWINGS

Advantageous embodiments of the invention are shown in the figures and are explained in more detail in the subsequent description.

Shown are:

FIG. 1 a flowchart of a method according to the invention for determining service life according to one embodiment;

FIG. 2 a flowchart of a method according to the invention for training a neural network according to one embodiment; and

FIG. 3 a schematic diagram of a device according to the invention for determining service life.

The same reference signs refer in all figures to the same device components or the same method steps.

### DETAILED DESCRIPTION

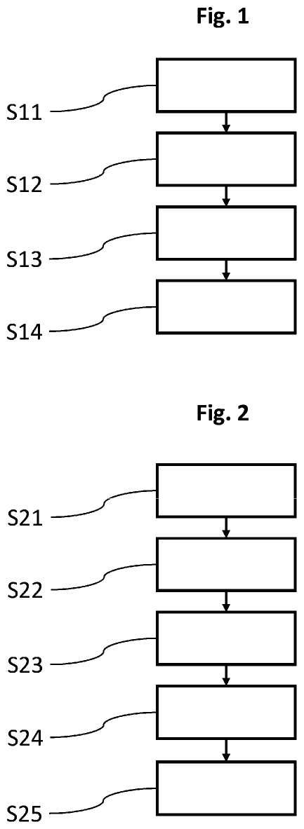

FIG. 1 shows a flowchart of a method according to the invention for determining service life according to one embodiment.

In a first step S11, a neural network with at least two input variables and an output variable is provided. For this purpose, a recurrent or feedback neural network in particular is suitable, since it can easily handle sequential input variables of different lengths.

In a second step S12, at least a current variable is determined, wherein the current variable represents an electrical current flowing through the switching device. Furthermore, in the second step S12, a switching device state variable is determined, which represents a sticking or jammed or fused switching device.

In a third step S13, the current variable and the switching device variable are transferred as input variables to the neural network. Depending upon the quantity of available data, the corresponding input variables can grow in size over time. In order to reflect the development over time, if required, a corresponding time stamp can also be stored. If the corresponding variables are always determined at the same time interval, it may be possible to dispense with this.

In a fourth step S14, a remaining service life of the switching device is then determined by means of the neural network. A warning can thus be output, for example, if the remaining service life falls below a predefined limit value.

FIG. 2 shows a flowchart of a method according to the invention for training a neural network according to one embodiment.

In a first step S21, data sets are provided which comprise at least a current variable, a switching device state variable, and an associated service life variable of a switching device. In this case, the current variable represents an electrical current flowing through the switching device, the switching device state variable represents a state of the switching device as stuck, jammed, or fused, and the service life variable represents a remaining service life of the switching device, wherein the definition of the remaining service life can be determined differently depending upon the application.

In a second step S22, a neural network with at least two input variables and an output variable is provided. This typically still has a standard parameterization, which does not yet reflect the findings from the training data.

In a third step S23, at least the current variable and the switching device state variable are input as input variables into the neural network. Accordingly, the neural network supplies an output variable.

In a fourth step S24, the output variable of the neural network is compared with the corresponding service life variable of the data sets. Typically, the corresponding variables are not the same, and the neural network must be adapted to reflect the reality more accurately.

In a fifth step S25, parameters of the neural network are therefore adapted as a function of the above comparison. Thus, the remaining service life of the switching device can be determined precisely by means of the adapted neural network.

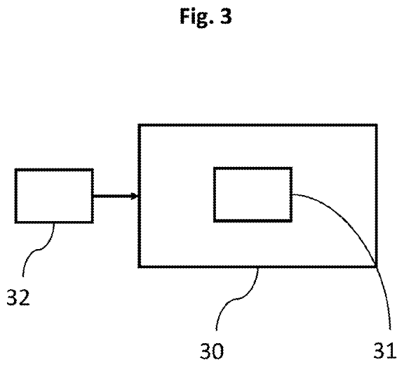

FIG. 3 shows a schematic diagram of a device 30 according to the invention for determining the service life of a switching device 32. The device 30 comprises an electronic computing unit 31, which is configured to carry out a method according to the invention. The current variable and the switching device state variable can be determined from a database, not shown here, which can also be included in the device 30. The corresponding data can be transferred, e.g., by means of a network connection, from the switching device 32 to this database, where they are accordingly available. For example, they can also be used for training a neural network.

1. A method for determining the service life of a switching device (32), the method comprising the steps of:
a) providing a neural network having at least two input variables and an output variable;
b) determining at least a current variable, which represents a current flowing through the switching device (32), and a switching device state variable, which represents a sticking or jammed or fused switching device (32);
c) inputting at least the current variable and the switching device state variable as input variables into the neural network; and
d) determining a remaining service life of the switching device (32) by means of the neural network.

2. The method according to claim 1, wherein the current variable is a continuous variable, and the switching device state variable is a discrete variable.

3. The method according to claim 1, wherein the neural network is trained by means of monitored learning.

4. The method according to claim 1, wherein at least the method steps i) and iii) are carried out in a cloud-based device.

5. A method for training a neural network for determining the service life of a switching device (32), the method comprising the steps of:
i) providing data sets, comprising at least a current variable, which represents a current flowing through the switching device, and a switching device state variable, which represents a sticking or jammed or fused switching device (32), and an associated service life variable, which represents a service life of the switching device (32);
ii) providing a neural network having at least two input variables and an output variable;
iii) inputting at least the current variable and the switching device state variable as input variables into the neural network;
iv) comparing the output variable of the neural network with the corresponding service life variable; and
v) adjusting parameters of the neural network as a function of the comparison.

6. A device for determining the service life of a switching device (32), comprising an electronic control unit (31) configured to
a) provide a neural network having at least two input variables and an output variable;
b) determine at least a current variable, which represents a current flowing through the switching device (32), and a switching device state variable, which represents a sticking or jammed or fused switching device (32);
c) input at least the current variable and the switching device state variable as input variables into the neural network; and
d) determine a remaining service life of the switching device (32) by means of the neural network.

7. A computer-readable storage medium containing instructions that when executed by a c computer cause the computer to
a) provide a neural network having at least two input variables and an output variable;
b) determine at least a current variable, which represents a current flowing through the switching device (32), and a switching device state variable, which represents a sticking or jammed or fused switching device (32);
c) input at least the current variable and the switching device state variable as input variables into the neural network; and
d) determine a remaining service life of the switching device (32) by means of the neural network.
